(19) United States
(12) Patent Application Publication
(10) Pub. No.: US 2013/0340814 A1
(43) Pub. Date: Dec. 26, 2013

(54) Photovoltaic module

(71) Applicant: Pierre-Yves Lahary, Lyon (FR)

(72) Inventor: Pierre-Yves Lahary, Lyon (FR)

(73) Assignee: SOLVAY ACETOW GMBH, Freiburg (DE)

(21) Appl. No.: 13/995,384

(22) PCT Filed: Dec. 20, 2011
(86) PCT No.: PCT/EP11/73338

§ 371 Date: Sep. 11, 2013

(30) Foreign Application Priority Data
Dec. 20, 2010 (FR) 1060824

(51) Int. Cl. H01L 31/048

(52) U.S. Cl. CPC H01L 31/0481
USPC 136/251

(57) ABSTRACT

A polymeric layer; and in particular the use of this polymeric layer as an outer protective layer of a photovoltaic module. The polymer of the layer is selected from the group consisting of cellulose and its derivatives; starch and its derivatives; alginates and their derivatives; guars and their derivatives; chitin and its derivatives; and pectin and its derivatives.

The present invention relates to a polymeric layer; and in particular the use of this polymeric layer as an outer protective layer of a photovoltaic module.

Global warming, linked to the greenhouse gases released by fossil fuels, has led to the development of alternative energy solutions which do not emit such gases during their operation, such as for example photovoltaic modules. A photovoltaic module comprises a “photovoltaic cell”, this cell being capable of converting light energy into electricity.

Photovoltaic modules generally have an outer protective layer made of glass, due to the need for a high light transmittance (>90.5%) and an excellent resistance to harsh climatic and environmental conditions (mainly moisture resistance, temperature resistance and UV resistance). However, the outer protective layer made of glass is generally heavy (density of the order of 2.5 g/cm³) and fragile.

It is known to use an outer protective layer made of acrylic. The drawback of such a layer is that it has a relatively low thermal resistance.

It is also known to use an outer protective layer made of polycarbonate. The drawback of such a layer is that it has a lower light transmittance than glass.

New high-performance materials are constantly being sought.

For this purpose, the invention proposes a photovoltaic module comprising at least one outer protective layer, an inner layer capable of converting solar radiation into electricity, and a protective layer at the back of the module (backsheet), the outer protective layer comprising at least one polymer chosen from the following polymers: cellulose and its derivatives, starch and its derivatives, alginates and their derivatives, guars and their derivatives, chitin and its derivatives and pectin and its derivatives.

The polymer of the outer protective layer may, for example, be one of the polymers below: cellulose, cellulose acetate, cellulose propionate, cellulose butyrate, cellulose triacetate, ethyl cellulose, hydroxy ethyl cellulose, methyl cellulose, hydroxy methyl cellulose, starch, hydroxypropyl starch, starch acetate, starch propionate, starch butyrate or mixed esters of starch, gum arabic, agar-agar, alginic acid, sodium alginate, potassium alginate, calcium alginate, gum tragacanth, guar gum and carob gum.

In particular, the polymer may be a derivative of cellulose, for example cellulose acetate, cellulose propionate, cellulose butyrate, cellulose triacetate, ethyl cellulose, hydroxy ethyl cellulose, methyl cellulose and hydroxy methyl cellulose.

According to one particular embodiment of the invention, the cellulose derivative is obtained from cellulose derived from premium wood pulp, or from cellulose derived from cotton linter. The expression “premium wood pulp” is understood to mean a wood pulp comprising at least 95% by weight of a-cellulose. The amount of α-cellulose is determined according to the ISO 692 standard. As regards the cellulose derived from cotton linter, it is preferably an acetate grade.

More particularly, the polymer may be a cellulose ester. They are generally organic, and in particular aliphatic, esters.

Advantageously, the cellulose ester has an acyl group having from 2 to 4 carbon atoms as ester group. These may be mixed esters of cellulose. Mention may be made, as an example of a suitable cellulose ester within the context of the invention, of: cellulose acetate, cellulose propionate, cellulose butyrate, cellulose acetopropionate, cellulose acetobutyrate, cellulose acetatophthalate and cellulose acetate propionate butyrate. The butyryl group forming the butyrate may be linear or branched.

Advantageously, the degree of substitution of the cellulose is between 2 and 3, preferably between 2.3 and 2.9. The degree of substitution of the cellulose is determined according to the ASTM D871-72 standard.

The intrinsic viscosity of the polymer of the invention is advantageously between 0.3 and 0.4, preferably between 0.32 and 0.35. The intrinsic viscosity is measured according to the ASTM D871-72 standard.

The polymer of the outer protective layer may be a blend of several polymers.

Preferably, the polymer is cellulose acetate.

The outer protective layer advantageously comprises at least 50% by weight of polymer, preferably at least 55% by weight.

According to one particular embodiment of the invention, the outer protective layer comprises a plasticizer. Mention may be made, as examples of plasticizers, of triacetin, diethyl phthalate, dimethyl phthalate, butyl phthalyl butyl glycolate, diethyl citrate, dimethoxy ethyl phthalate, ethyl phthalyl ethyl glycolate, methyl phthalyl ethyl glycolate, n-ethyl-o/p-toluenesulfonamides, triphenyl phosphate, tricresyl phosphate, dibutoxyethyl phthalate, diamyl phthalate, tributyl citrate, tributyl acetyl citrate, tripropyl acetyl citrate, tripropionin, tributyrin, o/p-toluenesulfonamide, pentaerythritol tetraacetate, dibutyl tartrate, diethylene glycol diacetate, diethylene glycol dipropionate, dibutyl adipate, dioctyl adipate, dibutyl azelate, trichloroethyl phosphate, tributyl phosphate, di-n-butyl sebacate, dibutyl phthalate, dioctyl phthalate, butylbenzyl phthalate, 2-ethylhexyl adipate and di-2-ethylhexyl phthalate. The amount of plasticizer is advantageously between 10% and 45% by weight relative to the weight of the outer protective layer, preferably between 20% and 40% by weight.

According to one particular embodiment of the invention, the outer protective layer comprises a heat stabilizer (that protects against thermal and/or thermo-oxidative degradation), such as an antioxidant. Mention may be made, as examples of heat stabilizers, of glycidyl ethers, metal salts of weak acids, substituted phenols, etc. In particular, mention may be made of hydroquinone monoglycidyl or diglycidyl ethers, potassium oxalate, strontium naphthenate, resorcinol diglycidyl ether, magnesium or aluminum formate, magnesia, etc.

Mention may be made, as examples of antioxidants, of hindered phenolic antioxidants. Such antioxidants are, for example, described in patent applications WO 2004/000921 and WO 02/053633. Irganox 1076® (octadecyl 3,5-di-tert-butyl-4-hydroxyhydrocinnamate) and Irganox 1010® (tetrakis(methylene(3,5-di-tert-butyl-4-hydroxyhydrocinnamate)methane)) are examples of such antioxidants.

Mention may also be made, as examples of antioxidants, of phosphorus-containing stabilizers such as phosphites substituted by alkyl and/or aryl radicals, for example Irgafos 168® (tris-(2,4-di-tert-butylphenyl)phosphite).

According to one particular embodiment of the invention, the outer protective layer comprises a light stabilizer.

Mention may be made, as examples of light stabilizers, of the stabilizers having at least one hindered amine unit (Hindered Amine Light Stabilizer H.A.L.S.). Such additives are, for example, described in patent applications WO 2004/000921 and WO 2005/040262.

As examples of light stabilizers, mention may also be made of UV absorbers. Such UV absorbers are in particular described in patent application WO 2004/000921. Mention may be made, as examples of UV absorbers, of oxanilides, benzophenones such as Uvinul 400® (2,4-dihydroxybenzophenone), benzotriazoles such as Tinuvin 360® (dimeric 2-hydroxyphenylbenzotriazole) or 2,2′-methylenebis[6-(2H-benzotriazol-2-yl)-4-(1,1,3,3-tetramethylbutyl)phenol], 2-hydroxyphenyltriazines such as Tinuvin 1577FF® (2,4-diphenyl-6-(2-hydroxy-4-hexyloxyphenyl)-s-triazine) and Tinuvin 234® (2-(2H-benzotriazol-2-yl)-4,6-bis(1-ethyl-1-phenylethyl)phenol).

The outer protective layer may also comprise one or more additives chosen from fillers, dyes, pigments, antistatic agents, surfactants, lubricants, dispersants, flame retardants, molding aids and impact modifiers (which must have a refractive index close to that of the polymer of the outer protective layer in order to maintain the transparency). This list is not limiting. The additives must be chosen and used in minimal amounts, in order to prevent interference with the transmission of solar radiation through the outer protective layer.

According to one particular embodiment of the invention, the outer protective layer does not comprise a metallic compound.

The outer protective layer may be prepared according to a known layer preparation process, for example by extrusion, injection molding, compression molding, cast molding, calendering, etc.

It is possible, initially, to prepare granules consisting of the constituent compound(s) of the outer protective layer, for example by extrusion in the form of rods, of the polymer or of a composition comprising the polymer that forms the outer protective layer; which rods are then cut in order to form granules. The additives such as plasticizers, stabilizers, etc. may be introduced at different locations of the extrusion device, for example at different locations of a twin-screw extruder. The granules may then be introduced into a layer transformation and shaping device as described above.

The outer protective layer is generally a sheet. Advantageously, the thickness of the outer protective layer is between 0.025 mm and 15 mm, preferably between 0.05 mm and 10 mm, more preferably between 0.5 mm and 8 mm, more preferably still between 1 mm and 8 mm, very particularly between 2 mm and 6 mm.

The surface of the outer protective layer of the invention may be covered with one or more coatings of another material. This may be a coating for protection against dirt, against abrasion, etc. This (these) coating(s) may be made, for example, from a fluoropolymer such as polyvinylidene fluoride (PVDF).

The photovoltaic module may be rigid or flexible.

Preferably, the outer protective layer of the invention is optically transparent, that is to say that it has a light transmittance of at least 88% according to the ASTM D1003 standard.

In addition to the outer protective layer, the photovoltaic module comprises an inner layer that can convert solar radiation into electrical energy, this layer generally being encapsulated, and a protective layer at the back of the module (backsheet).

The inner layer of the photovoltaic module consists of a material capable of converting solar radiation into an electric current.

In order to form the inner layer, it is possible to use photovoltaic sensors of any type, which include “conventional” sensors based on monocrystalline or polycrystalline doped silicon; thin film sensors formed, for example, of amorphous silicon, cadmium telluride or copper indium diselenide, or organic materials may also be used.

The photovoltaic sensors are often fragile, and thus they are generally encapsulated in order to be protected. Any known encapsulant may be used. Mention may be made, by way of example, of poly(ethylene/vinyl acetate) with peroxides and stabilizers, or thermoplastic encapsulants based on a-olefins, ionomers, silicones, polyvinyl butyral, etc.

In regards to the “backsheet”, it must give the photovoltaic module moisture impermeability, good creep resistance, good tear strength (that is to say that a film produced from the composition must have a good mechanical strength), and good electrical insulation. These are generally multilayer films based on a fluoropolymer (such as polyvinyl fluoride PVF or polyvinylidene fluoride PVDF) and/or on a polyester such as polyethylene terephthalate (PET).

Generally, in order to form a photovoltaic module, placed successively on a “backsheet” are a lower first layer of encapsulant, the photovoltaic inner layer, an upper second layer of encapsulant and then the outer protective layer. Additional layers may also be found between these layers, in particular binder or adhesive layers. These various layers are assembled in order to form the module.

In order to assemble the various layers, it is possible to use all types of pressing techniques such as, for example, hot pressing, vacuum pressing or laminating, in particular hot laminating. The manufacturing conditions will be easily determined by a person skilled in the art by adjusting the temperature and the pressure to the flow temperature of the composition. In order to manufacture the photovoltaic modules according to invention, a person skilled in the art may refer, for example, to the Handbook of Photovoltaic Science and Engineering, Wiley, 2003. In the laminating process for example, the components of the module are heated to a temperature generally between 110° C. and 150° C. in order to enable the crosslinking of the encapsulant. The outer protective layer in particular must therefore have a good resistance to these temperatures.

According to one particular embodiment of the invention, the photovoltaic module is a concentrated photovoltaic module. Concentrated photovoltaic modules are known to a person skilled in the art. Such modules generally comprise Fresnel lenses intended to concentrate the solar radiation on the photovoltaic cells. Compared to conventional photovoltaic modules, these modules are subjected, due to the concentration of the solar radiation, to large thermal stresses. The outer protective layer of these modules must therefore have a good thermal resistance.

The outer protective layer of the invention has very good properties for the application thereof in photovoltaic modules. Specifically, it is transparent (it has a high light transmittance) and light, and it has good mechanical properties, in terms of modulus in particular. It can be obtained in various sizes and shapes, and it is suitable for mass production. Another advantage of the outer protective layer of the invention is that it is made from a bio-based material.

Other details or advantages of the invention will become more clearly apparent in light of the examples given below.

### EXAMPLES

### Example 1

Disks of plasticized cellulose acetate for the outer protective layer of a photovoltaic module were prepared in this example.

A cellulose acetate having a degree of substitution of 2.45 and an intrinsic viscosity of 0.342 in accordance with the ASTM D871-72 standard was plasticized by 30% by weight of triacetin sold by the company Eastman.

This material was prepared under the following conditions. An Evolum 32® co-rotating twin-screw extruder sold by the company Clextral, having a diameter D=32 mm and a ratio of length to diameter L/D=44, was used. The cellulose acetate powder was introduced via the feed hopper and the liquid plasticizer (triacetin) was introduced at the start of the screw via a specific feed channel. The processing conditions applied were the following:
rotational speed of the screws: 100 rpm;
throughput: 10 kg/h;
temperature profile from the feed hopper to the die: from 80° C. to 160° C.

On leaving the extruder, the rod of plasticized cellulose acetate was granulated.

The granules thus prepared were then shaped by injection molding with an Arburg 350-90® press (mold closing force of 35 tonnes). Disks of plasticized cellulose acetate having a diameter of 85 mm and a thickness of 3 mm were obtained under the following conditions:
temperature profile of the single-screw extruder from the feed hopper: 160° C.-172° C.-172° C.-179° C.;
mold temperature: 70° C.
length of the injection cycle: 37.8 s.

A Konica Minolta CM-5® spectrophotometer was then used in order to measure the transmittance in accordance with the ASTM D1003 standard. A transmittance of 94.3% at 700 nm was obtained for this 3 mm thick sample.

### Example 2

In this example, a cellulose acetate butyrate CAB 381-2® sold by the company Eastman was plasticized by 10% by weight of triacetin sold by the company Aldrich. The following additives were added to the formulation:
antioxidants:
   0.5% by weight of Irganox 1010® (tetrakis(methylene-(3,5-di-(tert)-butyl-4-hydrocinnamate))methane) (sold by the company Ciba);
   0.5% by weight of Irgafos 168® (tris(2,4-di-tert-butylphenyl)phosphite) (sold by the company Ciba);
UV absorber:
   0.3% by weight of Tinuvin 234® (2-(2H-benzotriazol-2-yl)-4,6-bis(1-ethyl-1-phenylethyl)phenol) (sold by the company Ciba).

1. A photovoltaic module comprising at least one outer protective layer, an inner layer capable of converting solar radiation into electricity, and a protective layer at the back of the photovoltaic module, wherein said outer protective layer comprises at least one polymer selected from the group consisting of cellulose and its derivatives; starch and its derivatives; alginates and their derivatives; guars and their derivatives; chitin and its derivatives; and pectin and its derivatives.

2. The photovoltaic module according to claim 1, wherein said polymer is an ester.

3. The photovoltaic module according to claim 1, wherein said polymer is a cellulose ester.

4. The photovoltaic module according to claim 3, wherein said polymer is cellulose acetate.

5. The photovoltaic module as according to claim 1, wherein said outer protective layer comprises at least 50% by weight of said polymer.

6. The photovoltaic module according to claim 1, wherein said outer protective layer comprises a plasticizer.

7. The photovoltaic module according to claim 1, wherein said outer protective layer comprises a heat stabilizer.

8. The photovoltaic module according to claim 1, wherein said outer protective layer comprises a light stabilizer.

9. The photovoltaic module according to claim 1, further comprising one or more polymeric coatings on an outer surface exposed to the outside environment of said outer protective layer, said one or more polymeric coatings adhering to said outer protective layer.

10. The photovoltaic module according to claim 1, being a concentrated photovoltaic module.
